(19) United States
(12) Patent Application Publication
(10) Pub. No.: US 2008/0233709 A1
(43) Pub. Date: Sep. 25, 2008

(54) METHOD FOR REMOVING MATERIAL FROM A SEMICONDUCTOR

(75) Inventors: Richard Anthony Conti, Katonah, NY (US); Armin T. Tilke, Dresden (DE); Chris Stapelmann, Tervuren (BE); Michael R. Sievers, Poughkeepsie, NY (US)

Correspondence Address: INFINEON TECHNOLOGIES NORTH AMERICA CORP., 3000 CENTREGREEN WAY, CARY, NC, 27513, US

(73) Assignees: Infineon Technologies North America Corp., Milpitas, CA (US); International Business Machines, Armonk, NY (US)

(21) Appl. No.: 11/689,884

(22) Filed: Mar. 22, 2007

(51) Int. Cl. H01L 21/762; H01L 21/311

(52) U.S. Cl. 438/424; 438/694; 257/E21.545; 257/E21.249

(57) ABSTRACT

A method for removing a material from a trench in a semiconductor. The method includes placing the semiconductor in a vacuum chamber, admitting a reactant into the chamber at a pressure to form a film of the reactant on a surface of the material, controlling the composition and residence time of the film on the surface of the material to etch at least a portion of the material, and removing any unwanted reactant and reaction product from the chamber or the surface of the material.

### BACKGROUND OF THE INVENTION

The invention pertains to semiconductor fabrication. More particularly, the invention pertains to the creation of trenches during semiconductor fabrication.

It is often necessary to create trenches in one or more layers of a semiconductor substrate or other layer. For instance, the active regions of a MOSFET commonly are separated by isolation regions that electrically isolate the adjacent semiconductor devices from each other. These isolation regions typically are in the form of trenches etched into the semiconductor substrate and filled with a dielectric material to provide electrical isolation between the active regions.

For these and other reasons there is a need for the present invention.

### SUMMARY OF THE INVENTION

One aspect of the invention provides a method for removing a material from a trench in a semiconductor. The method includes placing the semiconductor in a vacuum chamber, admitting a reactant into the chamber at a pressure sufficient to form a film of the reactant on a surface of the material, controlling the composition and residence time of the film on the surface of the material to etch a portion of the material, and removing any unwanted reactant and reaction product from the chamber or surface of the material.

### BRIEF DESCRIPTION OF THE DRAWINGS

FIGS. 1A-1F are schematic diagrams illustrating an exemplary portion of a semiconductor at various junctures during fabrication in accordance with an embodiment of the present invention.

FIG. 2 is a cross-sectional side view of an apparatus for etching fill material in accordance with an embodiment of the present invention.

### DETAILED DESCRIPTION OF THE INVENTION

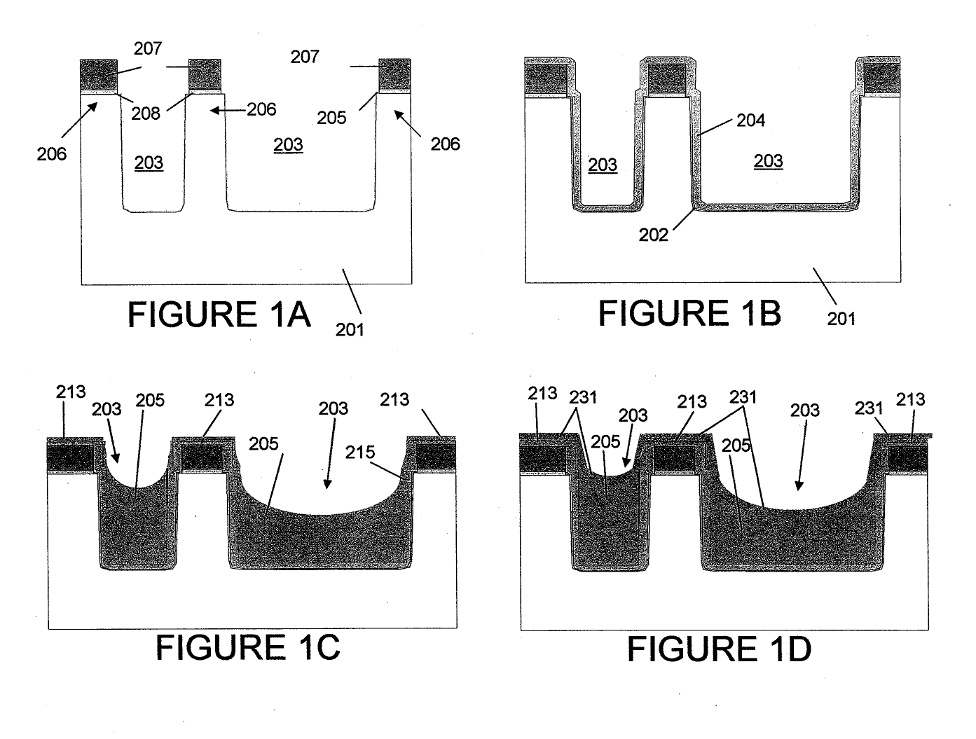

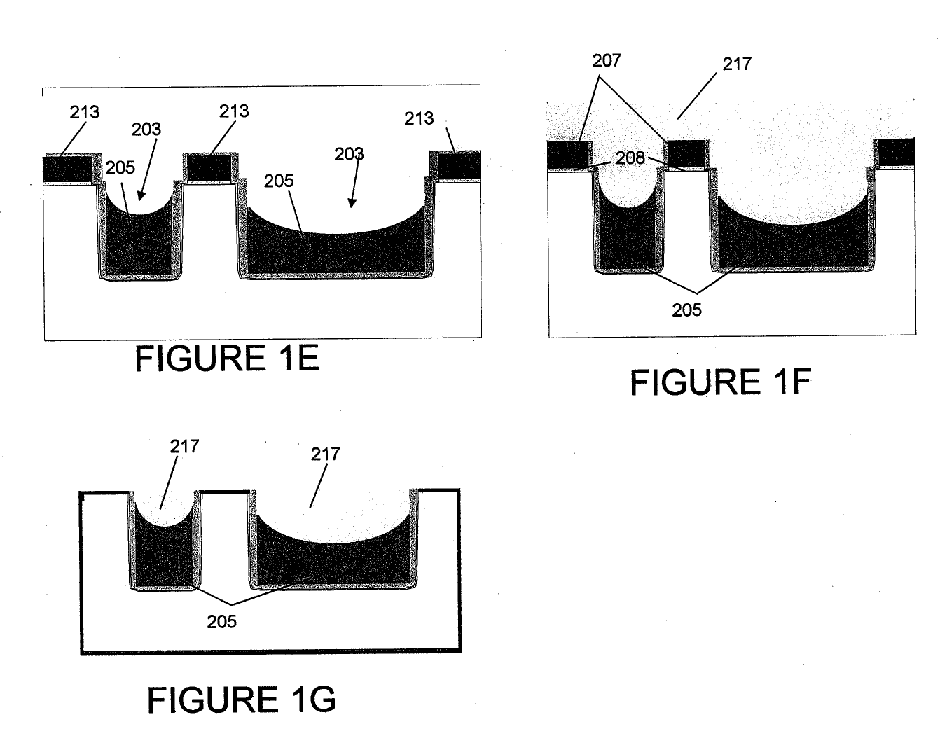

FIGS. 1A-1F help illustrate a method for filling a trench such as an STI trench in accordance with a particular embodiment of the present invention.

With reference to FIG. 1A, the process starts with a substrate 201 in which active regions 206 have already been defined and in which trenches 203 have already been etched. Further, the active regions 206 have been covered with a thin oxide layer 208 and a thick nitride layer 207, as is common. The thin oxide layer 208 and the nitride layer 207 are merely exemplary.

Next, with reference to FIG. 1B, one or more liners, such as an oxide liner 202 and a nitride liner 204, may be formed in the trenches 203. Specifically, one or more liners usually are formed in the trenches before the trenches are filled with silicon oxide. The oxide liner and the nitride liner may be formed by any suitable technique. Commonly, a first oxide liner 203 is grown by thermal oxidation to line the trenches. Specifically, the oxide liner 203 creates an improved sidewall interface to reduce defects and potential leakage paths. It also helps prevent dopants in the active regions from defusing from the active regions into the trenches.

FIG. 1B also illustrates an exemplary second, nitride liner 204. Merely as an example, a nitride liner 204 may be included as an etch stop layer to protect the underlying oxide liner 202 from one or more subsequent fabrication steps.

Turning to FIG. 1C, after any trench liners are deposited, the trenches 203 are filled. HDP CVD is a common technique for filling STI trenches, but problems have arisen with HDP CVD processes in smaller STI trenches. Particularly, as the trenches have become smaller, the widths of the trenches typically have decreased at a greater rate than the depths of the trenches. This leads to trenches having greater aspect ratios (the ratio of the depth to the width of the trench), which makes it difficult to fill the trench using HDP CVD without voids forming in the fill material. For semiconductor fabrication processes of scales less than 45 nm, fill techniques other than HDP CVD have been used. One such technique involves filling the trenches with a flowable liquid material, and then curing the flowable material. The flowable liquid fill materials can more easily flow into the trenches and achieve void free fill of the trenches. One such technique is known as Spin On Glass (SOG). Another technique that has been developed is known as FlowFill™, which is a proprietary process module available from Aviza Technologies, Inc. of Scotts Valley, Calif., USA. The particular flowable material can take any suitable form, but typically will comprise either silicon oxide (with or without impurities) or a low k dielectric, e.g., k≦3.9 (which is the k value of silicon dioxide). The trenches also may be filled by a condensation process.

As illustrated in FIG. 1C, flowable processes are bottom-up fill processes, i.e., the flowable material 205 fills the trenches 203 from the bottom up. Nevertheless, a thin layer of the flowable material 205 usually forms on the side walls 215 of the trenches and on the horizontal surfaces 213 above the active regions.

While such techniques effectively fill trenches, the fill materials typically used with these techniques are not as dense as the dense oxide that would be deposited by an HDP CVD process. Hence, use of these materials as the trench fill material makes it more difficult to control some of the subsequent fabrication processes that may be performed over the flowable fill material. Accordingly, when a flowable fill material is used to fill the trenches, it typically will be desirable to add a dense oxide layer (or cap) by HDP CVD over the filled trench in order to provide a layer of dense oxide so that subsequent fabrication steps can be performed more controllably.

However, before the dense oxide cap is deposited by HDP CVD, any flowable fill material 205 that has formed on the horizontal surfaces 213 above the active regions 206 of the substrate 201 as well as on the tops of the side walls 215 of the trenches should be removed. Specifically, the dense oxide HDP CVD cap usually is deposited in a thick layer over the substrate and subsequently etched back down to be level with the top surface of the substrate. Thus, the flowable material 205 should be removed from the tops of the side walls 215 of the trenches and from the sides and tops of the active regions 206 so as to avoid problems when this dense oxide cap is etched back to the level of the surface of the substrate. Specifically, the etchant for etching the dense oxide cap should not be permitted to contact the flowable fill material because the etchant for the dense oxide cap also will etch the flowable material (which typically will also be an oxide and, in fact, a less dense oxide than the cap) much more quickly than the dense oxide cap.

Thus, the thin layer of flowable material 205 at the tops of the side walls 215 of the trench 203 and on top of the horizontal surfaces 213 above the active regions should be removed from those regions prior to any deposition of a dense oxide cap over the flowable fill material 205.

Flowable fill materials tend to cure at different rates depending on the width of the trench. Particularly, the materials do not cure very well in narrower trenches. This makes it difficult to etch the thin layer of material near and above the top of the trench (which probably has cured quite well) using conventional wet etch techniques without also etching too much of the material deeper in narrow trenches (which probably has not been cured quite as well).

With reference to FIG. 1D, in accordance with an embodiment of the invention, this thin layer of fill material 205 is removed by condensing a reactant film over the fill material 205 and controlling the thickness, composition, and duration or the surface residence time of the condensed reactant film for purposes of accurately etching a desired thickness of the fill material. The process generally involves placing the substrate 201 having a trench filled with the fill material 205 that is to be etched in a reaction chamber, supplying a reactant to the chamber in such a manner that the reactant forms a film 231 on the surface of the material to be removed, the nature and duration of film being so controlled so that the film leads to the removal of an accurately controlled amount of the fill material 205 from the substrate 201. The etching of the fill material on the substrate occurs by chemical reaction of the reactants in the condensed film. An important feature of this process is that the apparatus and method for etching are designed to control the condensed or adsorbed film. This is unlike other techniques in which there is a constant rate of admission of the reactant gas into the reaction chamber and which do not permit controlling of the composition, thickness, or surface residence time of the film.

The technique involves detecting and controlling films of less than a layer thickness under real reaction conditions. This is accomplished through the use of a detection mechanism such as a quartz crystal microbalance and well defined reactants, thereby helping to classify the reaction into several regimes and to define preferred embodiments over a broad workable range of pressures and temperatures. The main regimes are reactions stemming from (1) adsorbed films of a layer or less, (2) condensed liquid films, and (3) condensed solid films. In a fourth regime, when there is no surface film, there is no reaction.

In a preferred embodiment, the reactants are ammonia and hydrogen fluoride gas.

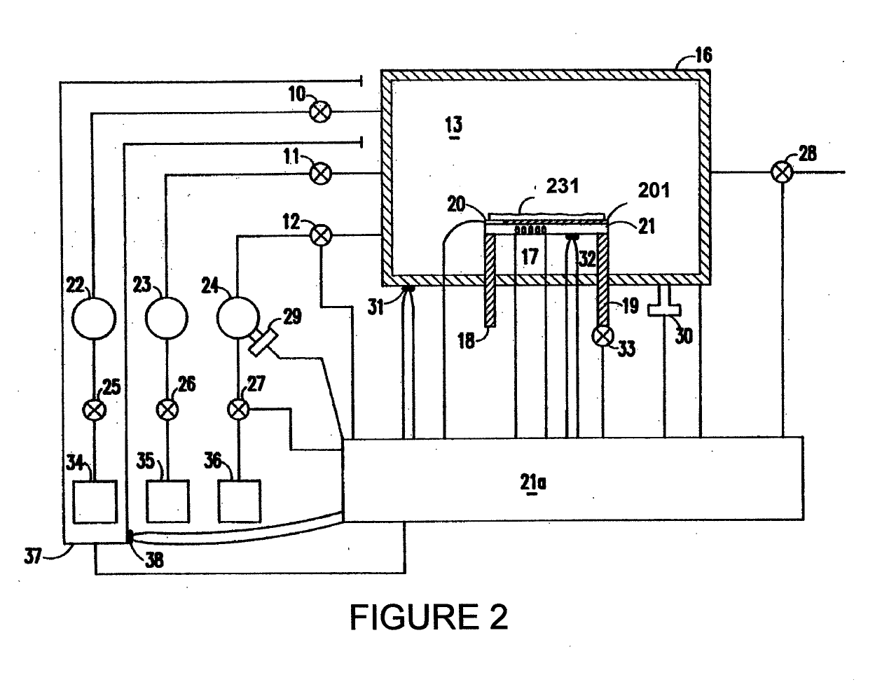

FIG. 2 illustrates an exemplary apparatus for etching the fill material 205 in accordance with an embodiment of the present invention. Valves 10, 11, and/or 12 are simultaneously opened in order to rapidly admit reactant, or reactant and catalyst, to the reaction chamber 13. Gas admission is rapid because the open diameter of valves 10, 11 and 12 is larger than the diameter of the regulating valve in a flowmeter. Immediately after admission, the pressure of the admitted gases is maintained above the condensation pressure at the temperature of the substrate 201. This results in the formation of a condensed film 231 on the surface of the substrate 201. While the pressure of the admitted gases is above the condensation pressure at the temperature of the substrate 201, the pressure of the admitted gases is below the condensation pressure at the temperature of the chamber 13, because the chamber is heated to above the substrate temperature by a first heater 16. The substrate 201 can be heated by a second heater 17 or cooled by flowing coolant in tubes 18 and 19. Both, a quartz crystal microbalance 20 containing a crystal coated with the same material as the layer to be etched, and the substrate 201 are attached to a substrate mount 21. The signals from the quartz crystal microbalance 20, reservoir pressure monitor 29, chamber pressure monitor 30, chamber temperature monitor 31, and substrate/microbalance temperature monitor 32, are fed to a controller 21a, which determines and regulates the pressure to which the reservoirs 22, 23, and 24 are filled. The reservoirs are filled from a source of the reactant 34 containing H₂O, 35 containing HF, and 36 containing NH₃; through valves 25, 26 and 27, respectively. Alternatively, reservoirs can hold solutions containing HF or NH₃ and a non-reactive gas could be bubbled through the solutions. The pressures in the reservoirs and chamber are regulated by connections between the controller 21a and valves 25, 26, 27, 10, 11, 12, and 28. Not all connections are shown in the drawing for the sake of simplicity. All sources, reservoirs, and tubing leading to the reaction chamber 13 can be heated to obtain reactant pressures greater than the room temperature vapor pressure. A heating shroud 37 is shown on one gas line source and reservoir. The signal from temperature sensor 38 is sent to controller 21 a which monitors and controls the temperature of the shroud 37. The shroud 37 and sensor 38 is shown for only one gas line to yield a simpler drawing. However, all lines may have a heating shroud and sensor controlled by 21a. The controller 21a monitors the temperature of chamber 13 with sensor 31 and controls the temperature through the connection to first heater 16. The controller 21a monitors the temperature of the substrate 14 and microbalance 20 with sensor 32 and controls the temperature through the connection to second heater 17 and coolant regulating valve 33. There are two modes of operation depending on whether valve 28 which leads to a vacuum pump (not shown) is open or closed during admission of reactant.

In a first such technique in which valve 28 to the vacuum pump is open, reactant, or reactant and catalyst are rapidly admitted into the reaction chamber 13 by opening valves 10, 11, and/or 12 simultaneously. Reservoir 23 is filled with HF and reservoir 24 with NH₃. Immediately after admission, the pressure of the admitted gases is maintained above the condensation pressure at the temperature of the substrate 201. This results in the formation of the condensed film 231 on the surface of the substrate 201. While the pressure of the admitted gases is above the condensation pressure at the temperature of the substrate, the pressure of the admitted gases is below the condensation pressure at the temperature of the chamber 13 because the chamber is heated to a temperature above the temperature of the substrate. A detector for detecting the film, such as quartz crystal microbalance 20 coated with the same film material as the substrate also is attached to the same mount 21 as the substrate 201 and maintained at the same temperature thereof.

HF and NH₃ are simultaneously and rapidly admitted into the chamber 13 from reservoirs 23 and 24. The reactant fills the chamber and rapidly condenses on the substrate and detector for a sufficiently short period of time when the pressure of the NH₃ and HF is above the vapor pressure at the temperature of the substrate so that a condensed film 231 is formed over the fill material 205. The film 231 reacts with the surface of the fill material 205 and etching is initiated. The chamber is maintained under vacuum through valve 28. Accordingly, the condensed film 231 decreases in thickness with time as HF and NH₃ at the vapor pressure of the condensed film is pumped out. Finally, all the condensed HF and NH₃ which is unreacted evaporates and is pumped out. The amount of fill material 205 that is removed depends on the substrate temperature, composition, and residence time of the reactant film 231. Factors influencing the amount of fill material removed include vapor pressure of the reactant at the temperature of the substrate, the amount of reactant admitted to the chamber, the pumping speed, and the reaction rate between the reactant and the film material, all of which can be regulated by suitable means.

In another mode of operation, valve 28 is closed so that the chamber is not under vacuum. Reservoir 22 is filled with H₂O vapor, and reservoir 23 is filled with HF, then valves 10 and 11 are opened to fill chamber 13. The reactant condenses on the substrate and the detector 20 to form a condensed film until the pressure in the chamber drops to the vapor pressure of the reactant at the temperature of the substrate. If the condensed film is a liquid, such as with admission of HF and H₂O with a substrate temperature above 0° C., then reaction can continue until all reactant in the condensed film has reacted. Alternately, the reaction can be stopped by opening valve 28 and applying a vacuum to the chamber at the desired time to evacuate the contents of the chamber. However, while the chamber 13 is not under vacuum, reactant in the chamber can exchange with a reactant in the film. The amount of the fill material 205 that is removed is determined by the amount of HF admitted to the chamber.

In accordance with another embodiment of the invention, the etching of the fill material 205 can be carried out at a low pressure. In such an embodiment, a reactant such as ammonium bifluoride is heated in order to vaporize it and then delivered to the chamber 13. The pressure in the chamber is maintained low enough so that the reactant molecules experience a small number of collisions as they pass from the admission aperture to the substrate 201. Low pressure is ensured by pumping the chamber. The incident reactant molecules condense when they strike the cooled substrate 201 and detector 20 to form a condensed film 231 of HF and NH₃ on the wafer. The temperature of the substrate required for condensation when reactant is present at low pressure is below the temperature required when reactant is at high pressure. Since the chamber pressure is low, there is little exchange between reactant in the gas phase in the chamber and the reactant condensed in the film on the surface of the substrate. Once the reaction is complete, evaporation of excess reactant and reaction with the film material layer 231 can be facilitated by increasing the substrate temperature with a heater.

In yet another embodiment, etching occurs in the adsorbed reactant regime. A key feature of this embodiment is a source of condensed reactant held at a temperature below the temperature of any other surface in the reaction chamber. Under these conditions, all molecules from the source can adsorb only on surfaces and are not able to condense to form multi-layer films. In this regime, there is a direct relationship between the composition of gases in the chamber and the composition of a surface film that contains the reactant. If the temperature of the substrate mount 21 is colder than the condensed source, then a multi-layer reactant film can form on the mount which can continue to desorb and produce gas phase reactant which adsorbs on the substrate 201 even after reactant is no longer intentionally added by the source of condensed reactant. In this embodiment, ammonium bifluoride solid is held within a container maintained at a temperature equal to or lower than the temperature of any other surface exposed to the vapor above the ammonium bifluoride. The chamber 13 contains a heater 16 so that the temperature of the walls is maintained at a temperature greater than or equal to the temperature of the container of the ammonium bifluoride. In the simplest mode of operation, the substrate, ammonium bifluoride, and chamber are all at room temperature. The chamber is evacuated, no vacuum is applied, and HF and NH₃ from an ammonium bifluoride cell is permitted to fill the chamber 13, rising within less than a minute to a “termination pressure”, which is approximately equal to the vapor pressure of the ammonium bifluoride at room temperature. Termination pressure is approximately equal to the vapor pressure of the condensed reactant in the source and is determined with the source, substrate, and chamber all at the same temperature. Once the “termination pressure” is determined, the temperatures and pumping speed can change and reaction will remain in the adsorbed film regime as long as the pressure in the chamber is equal to or below the “termination pressure” at the temperature of the substrate. When the HF and NH₃ fill the chamber, a film 231 of a monolayer or less in thickness, containing reactant, is adsorbed on the surface of the substrate 201 and on the surface of the detection mechanism 20. The pressure inside the chamber slowly rises beyond the termination pressure as a portion of the H₂O reaction product escapes from the product layer into the gaseous ambient inside the chamber. Assuming that the detector 20 is a quartz crystal microbalance coated with the same material as the layer that is to be etched away, the mass of the coated quartz crystal microbalance 20 increases as the product layer 231 is formed. The reactant gas is permitted to continue to enter the chamber 13. The mass increase from reaction is about twice the mass decrease from removal of silicon dioxide. This mass increase can be used directly to control the amount of silicon dioxide that is etched, because none of the reaction product is removed by simply exposing it to the ammonium bifluoride vapor and because thick reactant layers which could complicate the measurement do not form on the substrate when reaction occurs in the adsorbed film regime. After it is detected that the desired amount of silicon dioxide has been etched, no further reactant is allowed to enter the chamber and the chamber is evacuated.

U.S. Pat. No. 5,282,925 discloses suitable apparatus for achieving the aforedescribed processes for etching the fill material as well as additional detail concerning the processes and regimes described herein above. The process is a self limiting etching process. That is, its parameters can be set to etch a certain thickness of material and stop. It is considered to be a dry etch process. Hence, it should not be subject to the problems commonly associated with wet etch processes of removing more material in narrower trenches than in wider trenches. The process will remove the same amount of material in both wide trenches and narrow trenches.

The process removes materials such as oxide materials typically used to fill trenches independent of their deposition processes very reliably, evenly, controllably, and accurately. The parameters of the process can be set so as to etch completely through the thin layer of flowable material 205 at the tops of the side walls of the trenches and over the horizontal surfaces 213 of the top of the substrate to remove them completely, yet not remove any more material than necessary. Of course, essentially the same thickness of material as is removed from the tops of the side walls and the top of the substrate also will be removed from the bottom of the trench. However, this will typically be a tiny fraction of the thickness of the flowable material in the trench (probably less than 5%) and, therefore, should be acceptable.

After the etching process, the semiconductor substrate is in the state shown in FIG. 1E, in which the flowable material 205 has been removed from the tops of the side walls 215 of the trenches 203 and the horizontal surfaces 213 above the active regions, but substantially remains inside of the trenches. Next, a dense oxide cap 217 can be deposited, such as by HDP CVD or PECVD, as shown in FIG. 1F. Finally, the dense oxide cap 217 is reduced to the level of the top surface of the active regions as shown in FIG. 1G. More specifically, the cap 217 is first recessed to the top level of the thick nitride layer 207 (pad nitride), such as by CMP (Chemical Mechanical Polishing). Then, after a deglaze etch, the pad nitride 207, which served as a CMP stop layer, is stripped from the surface of the substrate by means of wet etch. Next, the oxide cap 217 is recessed to roughly the level of the upper surface of the substrate. Finally, the oxide layer 208 can be removed from the tops of the active regions 206.

FIG. 1G illustrates the condition of the semiconductor at the end of the process. From this point, the wafer can be processed to create whatever circuitry is desired to complete the overall fabrication of the semiconductor chip.

Having thus described a few particular embodiments of the invention, various alterations, modifications, and improvements will readily occur to those skilled in the art. Such alterations, modifications and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

1. A method for removing a material from a trench in a semiconductor, comprising:
placing the semiconductor in a vacuum chamber;
admitting a reactant into the chamber at a pressure sufficient to form a film of the reactant on a surface of the material;
controlling the composition and residence time of the film on the surface of the material to etch a predetermined portion of the material; and
removing any unwanted reactant and reactant products from the chamber or surface of the material.

2. The method of claim 1, wherein the film comprises a condensed or an adsorbed layer of reactant molecules, and wherein controlling the residence time and the composition of the film comprises maintaining a temperature of the semiconductor below the temperature of a surface of the chamber to reduce condensation of the reactant on the surface of the chamber.

3. The method of claim 1, wherein the film comprises a condensed or an adsorbed layer of reactant molecules, and wherein controlling the residence time and the composition of the film comprises maintaining a temperature of the semiconductor below the temperature of any other surface in the chamber to substantially eliminate condensation of the reactant on any other surface in the chamber.

4. The method of claim 1, wherein controlling the composition and the residence time of the film comprises controlling an amount of the reactant that is admitted into the chamber.

5. The method of claim 1, wherein the semiconductor comprises at least one trench, and wherein the material comprises fill material for the at least one trench.

6. The method of claim 5, wherein the at least one trench comprises one or more shallow trench isolation structures.

7. The method of claim 5, wherein the material has a dielectric constant that is equal to or less than 3.9.

8. The method of claim 5, wherein the material is deposited by a spin-on process.

9. The method of claim 5, wherein the material is deposited by a chemical vapor deposition process.

10. The method of claim 5, wherein said material is deposited by a condensation process.

11. The method of claim 5 wherein the material is deposited by a FlowFill™ process.

12. The method of claim 1, wherein the reactant comprises NH₃ and HF.

13. The method of claim 1, wherein the reactant comprises one or more materials selected from the group consisting of HF, H₂O, NH₃, ammonium bifluoride and a combination thereof.

14. The method of claim 13, wherein each one of the one or more materials is admitted separately into the chamber under a specific temperature and pressure.

15. The method of claim 14, wherein the temperature is less than or equal to a temperature of the semiconductor, wherein the reaction chamber is pumped out, a source of the one or more materials is opened, the reaction chamber is isolated from the pump by closing a shutoff valve so that the pressure within the chamber rises rapidly to a termination pressure, and after a reaction between the film and the material is substantially complete, the source is closed and the chamber is pumped out.

16. The method of claim 1, wherein the one or more materials comprise HF and NH₃, wherein the one or more materials are used to form a condensed layer to etch at least the portion of the material, wherein a reaction between the condensed layer and the material is controlled to a self-limiting thickness by adjusting a temperature, the pressure and a gaseous composition of HF and NH₃ in the chamber.

17. The method of claim 13, wherein the one or more materials comprise HF and ammonia, and wherein the one or more materials are used to form a condensed layer having a self-terminating thickness.

18. The method of claim 1, wherein controlling the composition and residence time of the film comprises admitting the reactant into the chamber at the pressure that is greater than a condensation pressure at a temperature of the semiconductor and that is less than the condensation pressure at the temperature of a surface of the chamber.

19. A method of creating an isolation structure in a semiconductor substrate, comprising:
providing a semiconductor substrate having a trench, wherein the trench includes a bottom surface, an open top, and a side surface that extends from the bottom surface to the top;
forming a liner along the bottom surface and the side surface of the trench;
filling the trench with a dielectric material;
removing the dielectric material from a portion of the side surface of the trench adjacent the opening while leaving most of the dielectric material in the trench so as to expose the liner on the portion of the side surfaces by:
placing the semiconductor substrate in a vacuum chamber;
admitting reactant containing gas into the chamber at a sufficient pressure so as to form a film of the reactant on a surface of the dielectric material; and
controlling the composition and residence time of the film on the surface of the dielectric material so as to etch an accurate amount of the dielectric material on the substrate; and
removing any unwanted reactant and reaction products from the chamber or surface of the substrate;
depositing an oxide over the trench to a level above the opening of the trench; and
recessing the oxide down to the level of the opening of the trench.

20. The method of claim 19, wherein forming the liner comprises forming a nitride liner.

21. The method of claim 19, wherein forming the liner comprises forming an oxide liner followed by a nitride liner.

22. The method of claim 19, wherein filling the trench with a dielectric material comprises filling the filling the trench with a dielectric material that has a dielectric constant that is equal to or less than 3.9.

23. The method of claim 19, wherein depositing the oxide comprises depositing the oxide using a chemical vapor deposition process.

24. The method of claim 19, wherein recessing the oxide comprises using a chemical mechanical polishing process or a wet etch process.

25. The method of claim 19, wherein controlling the composition and the residence time of the film comprises admitting the reactant into the chamber at the pressure that is greater than a condensation pressure at a temperature of the semiconductor substrate and that is less than the condensation pressure at the temperature of a surface of the vacuum chamber.

26. An isolation structure in a semiconductor substrate formed according to the method described in claim 1.
